(19) United States
(12) Patent Application Publication
(10) Pub. No.: US 2024/0318352 A1
(43) Pub. Date: Sep. 26, 2024

(54) METHOD AND APPARATUS FOR THE THERMAL POST-TREATMENT OF AT LEAST ONE SIC VOLUME MONOCRYSTAL

(71) Applicant: SiCrystal GmbH, Nürnberg (DE)

(72) Inventors: Bernhard Ecker, Nürnberg (DE); Maximilian Kowasch, Nürnberg (DE); Ralf Müller, Nürnberg (DE); Philipp Schuh, Nürnberg (DE); Matthias Stockmeier, Nürnberg (DE); Daisuke Takegawa, Nürnberg (DE); Michael Vogel, Nürnberg (DE); Arnd-Dietrich Weber, Nürnberg (DE)

(21) Appl. No.: 18/598,090

(22) Filed: Mar. 7, 2024

(30) Foreign Application Priority Data
Mar. 23, 2023 (EP) 23163761.2

(51) Int. Cl. C30B 33/02; C30B 29/36; F27B 17/00; F27D 5/00

(52) U.S. Cl. CPC C30B 33/02; C30B 29/36; F27B 17/0016; F27D 5/0037

(57) ABSTRACT

Thermal post-treatment of a silicon carbide (SiC) volume monocrystal which has a substantially cylindrical basic shape with a crystal length in an axial direction, a crystal diameter in a radial direction, a crystal central longitudinal axis extending in the axial direction, and with three boundary surfaces, namely, a bottom surface, a top surface and a circumferential edge surface. The SiC volume monocrystal is brought to a post-treatment temperature in order to reduce mechanical stresses present in the SiC volume monocrystal after completion of the previous growth, wherein an inhomogeneous temperature profile with a radial thermal gradient is set in the SiC volume monocrystal, which rises continuously from the crystal central longitudinal axis to the circumferential edge surface, and a heat exchange of the SiC volume monocrystal with a surrounding free space takes place via free heat radiation on at least two of the three boundary surfaces.

### CROSS-REFERENCE TO RELATED APPLICATION

This application claims the priority, under 35 U.S.C. § 119, of European patent application EP23163761.2, filed Mar. 23, 2023; the prior application is herewith incorporated by reference in its entirety.

### FIELD AND BACKGROUND OF THE INVENTION

The invention relates to a method for the thermal post-treatment of at least one SiC volume monocrystal which has a substantially cylindrical basic shape with a crystal length measured in an axial direction, with a crystal diameter measured in a radial direction, with a crystal central longitudinal axis extending in the axial direction and with three boundary surfaces, namely a bottom surface, a top surface and a circumferential edge surface. The invention also relates to an apparatus for the thermal post-treatment of at least one such SiC volume monocrystal.

Due to its outstanding physical, chemical, electrical and optical properties, the semiconductor material silicon carbide (SiC) is also used as a starting material for power electronic semiconductor components, for high-frequency components and for special light-emitting semiconductor components. SiC substrates (=SiC wafers) with the largest possible substrate diameter and the highest possible quality are required for these components. The basis for this is high-grade SiC volume monocrystals.

Such SiC volume monocrystals are usually produced by means of physical vapor deposition (PVT), e.g. by means of a sublimation method described in U.S. Pat. No. 8,865,324 B2. In that method, a monocrystalline SiC disc is introduced into a growth crucible as a SiC seed crystal together with suitable source material. Under controlled temperature, pressure and gas conditions, the source material is sublimated and the gaseous species (=SiC growth gas phase) are deposited on the SiC seed crystal, causing the SiC volume monocrystal to grow.

The disc-shaped monocrystalline SiC substrates are cut out of these SiC volume monocrystals, which are then provided with at least one epitaxial layer, consisting in particular of SiC, after a multi-stage polishing treatment of their surfaces as part of a component manufacturing process. As a rule, defects from the SiC substrate are inherited by the applied epitaxial layer and thus lead to a deterioration of the component properties. The quality of the components therefore depends largely on the quality of the grown SiC volume monocrystal and the SiC substrates obtained therefrom.

The geometry of the SiC substrate used is of great importance for the production of the epitaxial layers of the components. In an epitaxy reactor, for example, good thermal coupling, which is very important for homogeneous and high-quality epitaxial layer growth, is essentially only achieved with SiC substrates that do not have any significant bow. In contrast, SiC substrates with poor geometric properties, i.e. in particular with excessive bow and/or warp, inevitably lead to lower quality or lower yields from the epitaxy process.

German patent DE 10 2009 048 868 B4 describes a method for the thermal post-treatment of a SiC volume monocrystal in order to reduce thermal stresses within the SiC volume monocrystal and thus improve the crystal quality. After its growth, the SiC volume monocrystal is tempered in a crucible during an additional process step, where it is completely embedded in SiC powder. During the thermal post-treatment, the temperature field in the SiC volume monocrystal is as isothermal or homogeneous as possible. Preferably, the temperature difference measured in the direction of the central longitudinal axis (=axial) is set as low as possible, at a maximum of 2 K, in order to favor the equalization of mechanical stresses in the axial direction. However, such an isothermal temperature field can only have a global effect on stress fields in the SiC volume monocrystal, so that the mechanical stresses present in the crystal structure are only partially relieved.

U.S. Pat. No. 8,449,671 B2 describes a further method for the thermal post-treatment of a SiC volume monocrystal, which is intended to positively influence the geometry of the SiC substrates obtained therefrom. During this post-treatment, the SiC volume monocrystal is subjected to an axial temperature gradient which is in the opposite direction to the axial temperature gradient set during crystal growth. The SiC volume monocrystal to be tempered can rest on a graphite intermediate piece.

U.S. Pat. No. 7,767,022 B1 describes another method for the thermal post-treatment of a SiC volume monocrystal, in which it is either directly or indirectly completely embedded in a powdered polycrystalline SiC source material. In the case of indirect embedding, the SiC volume monocrystal to be tempered is located in a thin-walled container made of porous graphite of low density, which in turn is then placed inside the polycrystalline SiC source material. Tempering should take place at as uniform a temperature as possible. Preferably, both axial and radial temperature gradients are minimized.

### SUMMARY OF THE INVENTION

It is therefore an object of the invention to provide a further improved method as well as a further improved apparatus for the thermal post-treatment of a SiC volume monocrystal.

In order to achieve the object of the method, a method for the thermal post-treatment of at least one SiC volume monocrystal which has a substantially cylindrical basic shape with a crystal length measured in an axial direction, with a crystal diameter measured in a radial direction, with a crystal central longitudinal axis extending in the axial direction and with three boundary surfaces, namely a bottom surface, a top surface and a circumferential edge surface, is disclosed. In the method according to the invention, the SiC volume monocrystal is brought to a post-treatment temperature in order to reduce mechanical stresses present in the SiC volume monocrystal after completion of the previous growth, wherein an inhomogeneous temperature profile with a radial thermal gradient is set in the SiC volume monocrystal, which increases continuously from the crystal central longitudinal axis to the circumferential edge surface, and a heat exchange of the SiC volume monocrystal with a free space surrounding it takes place by means of free heat radiation on at least two of the three boundary surfaces.

The bottom surface of the SiC volume monocrystal is in particular essentially circular and preferably essentially flat. Preferably, but not necessarily, the bottom surface is formed by the underside of the SiC seed crystal used to grow the SiC volume monocrystal. Alternatively, the SiC seed crystal can also be separated from the portion of the SiC volume monocrystal grown during the previous growth prior to thermal post-treatment. The top surface of the SiC volume monocrystal is opposite the bottom surface. It is in particular uneven, preferably cap-shaped or dome-shaped. The circumferential edge surface is essentially in the form of a cylindrical surface. During its growth, the SiC volume monocrystal is grown in an axial direction. The term “axial” here refers to a direction parallel to or along the crystal central longitudinal axis, the term “radial” refers to a direction perpendicular thereto and the term “tangential” refers to a circumferential direction extending around the crystal central longitudinal axis.

It has been recognized that the radial thermal gradient, which prevails in the SiC volume monocrystal to be tempered during thermal post-treatment, is more important for the reduction of mechanical stresses in the crystal structure than the axial thermal gradient, which has so far been the main focus of known post-treatment processes. This is true in particular the larger the crystal diameter is.

During the sublimation growth of the SiC volume monocrystal, the growth interface is defined by isothermal lines of the temperature field. A curved growth interface is an important prerequisite for producing high-grade SiC volume monocrystals. The SiC volume monocrystal therefore grows in a curved temperature field during growth. Different temperatures prevail at the curved growth interface. This applies in particular to a temperature comparison between the centre and the edge region of the growth interface. These temperature differences generate dislocations and mechanical stresses in the growing SiC volume monocrystal. An SiC substrate that is later cut out of the SiC volume monocrystal also has partial regions that were grown at different temperatures during crystal growth. The resulting mechanical stresses in the SiC substrate are one cause of the aforementioned bow and/or warp. The curvature of the thermal fields set during growth also extends to a significant extent in a radial direction.

This is where the present invention comes in. It has been found that a thermal gradient that continuously increases in the radial direction, starting from the crystal central longitudinal axis, is a particularly effective thermal post-treatment measure to achieve the desired stress reduction in the SiC volume monocrystal and the resulting positive influence on the geometry of the SiC substrates obtained from the SiC volume monocrystal. Such a continuously increasing radial thermal gradient advantageously leads to a reduction or preferably even to a minimization of the stress balance in the crystal structure of the SiC volume monocrystal. In this context, stresses are to be understood in particular as frozen dislocations and/or other defects in the crystal lattice. During thermal post-treatment, the SiC volume monocrystal is brought to a post-treatment temperature at which these dislocations are preferably mobilized. They can then move within the crystal structure. A temperature gradient that increases continuously in the radial direction also defines a direction in which the mobilized dislocations prefer to move. In particular, the dislocations then move radially outwards or dissolve. This also favorably reduces the entropy in the SiC volume monocrystal.

It has also been recognized that this advantageous inhomogeneous temperature profile with a continuously increasing thermal gradient in the radial direction can be set particularly well by surrounding the SiC volume monocrystal during the thermal post-treatment, in particular on more than 50% of its entire crystal surface, by free space or by having more than 50% of its entire crystal surface adjacent to free space. In particular, the SiC volume monocrystal is contact-free at these points, i.e. it has no mechanical contact with other objects, such as an inner wall of the post-treatment crucible or a holding surface of the crystal holder, or with other materials, such as SiC powder material. Advantageously, the heat exchange between the SiC volume monocrystal to be tempered and the free space at these contact-free points, which are located on at least two of the three boundary surfaces of the SiC volume monocrystal, takes place by means of free heat radiation. In particular, the heat exchange in the non-contact regions, i.e. in the contacted points or regions of the SiC volume monocrystal, takes place mainly by means of heat conduction, wherein the proportion of the entire crystal surface with free heat radiation preferably dominates over the proportion of the entire crystal surface with heat conduction. Both mechanisms transfer heat to different degrees at the post-treatment temperature, the heat radiation mechanism in particular better than the heat conduction mechanism. The ratio of the proportion of the surface area with heat conduction to the proportion of the surface area with free heat radiation is, in particular, a preferred parameter for setting the inhomogeneous temperature profile with a thermal gradient that increases continuously in the radial direction.

In contrast to this, some of the thermal post-treatment methods known to date use the opposite temperature field. This applies in particular to post-treatment methods in which the SiC volume monocrystal is completely surrounded by SiC powder. This embedding is carried out in particular to prevent non-stoichiometric dissolution of the SiC volume monocrystal that may occur at high post-treatment temperatures. On the other hand, complete embedding in SiC powder reduces heat transport by heat radiation. Instead, the heat exchange with the environment takes place almost exclusively by means of heat conduction. As a result, these post-treatment methods result in a high temperature homogeneity in the SiC volume monocrystal to be tempered. For this reason, however, no similarly favorable stress relief can be achieved in the SiC volume monocrystal as in the post-treatment method according to the invention due to the inhomogeneous temperature profile with a continuously increasing radial thermal gradient. In addition, the method according to the invention has a further advantage over the known post-treatment method with embedding of the SiC volume monocrystal in SiC powder. Without such embedding, SiC may evaporate from the surface of the SiC volume monocrystal. However, this effect can be counteracted by adjusting, in particular increasing, the process pressure in the post-treatment crucible. On the other hand, dispensing with embedding in SiC powder offers the advantage that no parasitic SiC grows uncontrollably on the SiC volume monocrystal to be tempered during the thermal post-treatment according to the invention. Such growths of parasitic SiC can cause renewed and/or additional mechanical stresses in the edge region of the SiC volume monocrystal during cooling of an SiC volume monocrystal embedded in SiC powder after completion of the thermal post-treatment, which can have a negative effect on the geometry of the SiC substrates produced from the SiC volume monocrystal, in particular due to the bow and/or warp caused by these stresses.

Advantageous embodiments of the method according to the invention result, inter alia, from the features described hereinafter.

In a favorable embodiment, the heat exchange of the SiC volume monocrystal with the surrounding free space takes place by means of free heat radiation at all three boundary surfaces. In particular, contact-free points or regions of the SiC volume monocrystal can be located on all three of its boundary surfaces, wherein the respective boundary surface can preferably be completely or only partially contact-free. Heat exchange by means of heat radiation is then particularly efficient. At the non-contact-free points or regions of the SiC volume monocrystal, i.e. those that are contacted, on the other hand, heat exchange takes place mainly by means of heat conduction.

According to a further favorable embodiment, the heat exchange of the SiC volume monocrystal with the free space surrounding it takes place by means of free heat radiation at a radiation surface portion of a total surface area of the SiC volume monocrystal, wherein the total surface area is composed of the sum of the three boundary surfaces and the radiation surface portion is in the range from 63% to 83%, in particular from 63% to 78% of the total surface area. This allows the inhomogeneous temperature profile to be adjusted particularly well with the thermal gradient rising continuously radially from the crystal central longitudinal axis. The radiation surface portion is in particular the portion of the total surface area that is not in contact with other objects or materials. It is therefore preferably contact-free.

According to another favorable embodiment, the radial thermal gradient is set so that it takes values between 0.1 K/cm and 0.3 K/cm, in particular between 0.1 K/cm and 0.25 K/cm, in a central region of the SiC volume monocrystal, which extends in the radial direction from the crystal central longitudinal axis to half the crystal diameter. This results in particularly good stress relief in the crystal structure of the SiC volume monocrystal.

According to a further favorable embodiment, the radial thermal gradient is set so that it takes values between 0.25 K/cm and 0.8 K/cm, in particular between 0.25 K/cm and 0.7 K/cm, in an edge region of the SiC volume monocrystal that extends in the radial direction from half the crystal diameter to the circumferential edge surface. This measure also favors stress relief in the crystal structure of the SiC volume monocrystal.

According to another favorable embodiment, a temperature value is set for the post-treatment temperature which is higher, in particular up to 500° C. higher, preferably up to 200° C. higher than a growth temperature at which the SiC volume monocrystal has previously been grown. In particular, a post-treatment temperature of greater than 1950° C., preferably greater than 2000° C., preferably greater than 2,200° C. is set, wherein an upper limit value of this temperature is in particular 2,500° C., preferably 2,450° C.

According to yet another favorable embodiment, a gas atmosphere is established around the SiC volume monocrystal, for which purpose at least one silicon-free process gas is supplied. Preferably, the at least one silicon-free process gas is a gas from the group of argon, helium, another noble gas and nitrogen or a gas mixture from this group. The thermal post-treatment of the SiC volume monocrystal is carried out in particular without the active addition of silicon-containing components, such as gases or solids. In particular, no silicon-containing components, gases or solids, such as SiC powder, are introduced into the post-treatment crucible. The SiC volume monocrystal to be tempered preferably does not come into direct contact with such silicon-containing components. Indirect contact, such as could be achieved by interposing a barrier, e.g. in the form of a porous separating element or a porous membrane, is in particular not present here. This prevents the formation of a silicon-containing atmosphere in the post-treatment crucible due to the active supply of silicon-containing components. In particular, any small amounts of silicon-containing gas content present in the atmosphere nevertheless originate essentially only from the SiC volume monocrystal to be tempered itself, for example due to evaporation of SiC from the surface of the SiC volume monocrystal.

According to a further favorable embodiment, a process gas pressure is set in the range between 800 mbar and 1200 mbar, in particular in the range between 800 mbar and 1000 mbar.

According to another favorable embodiment, the crystal length is at most 50 mm, in particular at most 45 mm. Preferably, it is between 25 mm and 30 mm. A lower limit value for the crystal length is in particular 15 mm, preferably 25 mm and most preferably 30 mm.

According to yet another favorable embodiment, the crystal diameter is at least 150 mm, in particular at least 200 mm. An upper limit value for the crystal diameter is in particular 450 mm, preferably 300 mm. As the crystal diameter increases, the probability increases that SiC substrates produced from the SiC volume monocrystal will have disturbing bows and/or warps induced by thermally induced mechanical stresses in the crystal structure of the SiC volume monocrystal. In particular, this applies to SiC volume monocrystals with a crystal diameter of about 150 mm and larger. Therefore, the post-treatment method according to the invention is particularly advantageous and efficient for a SiC volume monocrystal with such a large crystal diameter, since the mechanical stresses which are then increasingly present in the crystal structure of the SiC volume monocrystal are relieved.

According to a further favorable embodiment, an aspect ratio, which is formed by dividing the crystal length by the crystal diameter, is in the range between 0.05 and 0.35, in particular in the range between 0.1 and 0.3. The crystal length of the SiC volume monocrystals, which can be produced by physical vapour deposition (PVT), is limited in particular to a few centimeters and is largely independent of the crystal diameter. As the crystal diameter increases, the aspect ratio of the SiC volume monocrystals changes. It becomes smaller and smaller. The radial thermal gradient increasingly dominates the properties of the growing SiC volume monocrystal compared to the axial thermal gradient as the crystal diameter increases. Consequently, the stresses in the growing SiC volume monocrystal and the influence on the geometry of the SiC substrates subsequently produced therefrom are increasingly determined by the radial thermal gradient prevailing during growth. It has been recognized that the axial thermal gradient is of secondary importance when the aspect ratio falls below a certain upper limit, which applies both to the growth and to the thermal post-treatment of the SiC volume monocrystal. This upper limit of the aspect ratio lies in particular in the range between 0.3 and 0.35. Instead, the decisive factor is the focus on the radial thermal gradient provided in the post-treatment method according to the invention in order to achieve the desired positive influence on the geometry of the SiC substrates produced from the SiC volume monocrystal to be tempered.

According to another favorable embodiment, the at least one SiC volume monocrystal to be thermally post-treated is placed on a crystal holder arranged in a post-treatment crucible with a holding surface for contacting and holding the at least one SiC volume monocrystal, wherein the holding surface contacts the at least one SiC volume monocrystal to be post-treated only in a radial edge region of the SiC volume monocrystal.

According to yet another favorable embodiment, an inner diameter of the post-treatment crucible is provided which is larger than the crystal diameter, so that when the SiC volume monocrystal is inserted in the post-treatment crucible, a tangentially completely circumferential free annular gap is present between the circumferential edge surface of the SiC volume monocrystal and an inner wall of the post-treatment crucible.

According to a further favorable embodiment, the crystal holder is designed as an annular crystal support.

According to another favorable embodiment, a thickness measured in the axial direction in the range between 1 mm and 5 mm, in particular in the range between 1 mm and 3 mm, is provided for the crystal support.

According to yet another favorable embodiment, a lower thermal conductivity is provided for a holder material of which the crystal holder consists or which it contains than that of a crucible material of which the post-treatment crucible consists or which it contains.

According to a further favorable embodiment, a higher porosity is provided for a holder material of which the crystal holder consists or which it contains than that of a crucible material of which the post-treatment crucible consists or which it contains.

In order to achieve the object of the apparatus, an apparatus for the thermal post-treatment of at least one SiC volume monocrystal, which has an essentially cylindrical basic shape with a crystal length measured in an axial direction, with a crystal diameter measured in a radial direction, with a crystal central longitudinal axis extending in the axial direction and with three boundary surfaces, namely a bottom surface, a top surface and a circumferential edge surface, is disclosed. The apparatus according to the invention has a thermal post-treating crucible with a receiving space for the at least one SiC volume monocrystal to be thermally post-treated, a heating device for heating the post-treatment crucible and the SiC volume monocrystal to be placed therein to a post-treatment temperature to reduce mechanical stresses present in the SiC volume monocrystal after completion of the preceding growth, and a crystal holder arranged in the post-treatment crucible with a holding surface for contacting and holding the at least one SiC volume monocrystal to be thermally post-treated. In this process, the holding surface contacts the at least one SiC volume monocrystal to be post-treated only in a radial edge region of the SiC volume monocrystal, so that an inhomogeneous temperature profile with a radial thermal gradient is established in the at least one SiC volume monocrystal to be post-treated, which rises continuously from the crystal central longitudinal axis to the circumferential edge surface, and a heat exchange of the at least one SiC volume monocrystal to be post-treated with a free space surrounding it takes place by means of free heat radiation on at least two of the three boundary surfaces, wherein the free space is part of the receiving space.

The radial edge region of the SiC volume monocrystal contacted by the holding surface of the crystal holder comprises in particular the circumferential edge surface as well as partial regions of the bottom surface and the top surface adjacent to the circumferential edge surface.

The apparatus according to the invention and the embodiments thereof offer essentially the same advantages that have already been described in connection with the method according to the invention and the embodiments thereof.

Advantageous embodiments of the apparatus according to the invention result, inter alia, from the features described hereinafter.

A favorable embodiment is one in which the crystal holder is configured in such a manner that the heat exchange of the SiC volume monocrystal with the surrounding free space takes place by means of free heat radiation on all three boundary surfaces.

According to a further favorable embodiment, the crystal holder is designed such that the heat exchange of the SiC volume monocrystal with the free space surrounding it takes place by means of free heat radiation on a radiation surface portion of a total surface area of the SiC volume monocrystal, wherein the total surface area is composed of the sum of the three boundary surfaces and the radiation surface portion is in the range from 63% to 83%, in particular from 63% to 78% of the total surface area.

According to another favorable embodiment, the contacting of the at least one SiC volume monocrystal by the holding surface is designed such that the radial thermal gradient in a central region of the SiC volume monocrystal takes values between 0.1 K/cm and 0.3 K/cm, in particular between 0.1 K/cm and 0.25 K/cm, wherein the central region of the SiC volume monocrystal extends in the radial direction from the crystal central longitudinal axis up to half the crystal diameter.

According to yet another favorable embodiment, the contacting of the at least one SiC volume monocrystal by the holding surface is designed such that the radial thermal gradient in an edge region of the SiC volume monocrystal takes values between 0.25 K/cm and 0.8 K/cm, in particular between 0.25 K/cm and 0.7 K/cm, wherein the edge region of the SiC volume monocrystal extends in the radial direction from half the crystal diameter to the circumferential edge surface.

According to a further favorable embodiment, the post-treatment temperature is a temperature value which is higher, in particular up to 500° C. higher, preferably up to 200° C. higher than a growth temperature at which the SiC volume monocrystal has previously been grown. In particular, the post-treatment temperature is greater than 1,950° C., preferably greater than 2,000° C., preferably greater than 2,200° C., wherein an upper limit value of this temperature is in particular 2,500° C., preferably 2,450° C.

According to another favorable embodiment, an inner diameter of the post-treatment crucible is larger than the crystal diameter, so that when the SiC volume monocrystal is inserted in the post-treatment crucible, a tangentially completely circumferential free annular gap is present between the circumferential edge surface of the SiC volume monocrystal and an inner wall of the post-treatment crucible. As a result, heat exchange takes place at the circumferential edge surface of the SiC volume monocrystal by means of free heat radiation with the free space that then also extends into the free annular gap. The annular gap has a gap width in particular in the range between 5 mm and 20 mm, preferably in the range between 5 mm and 15 mm.

According to yet another favorable embodiment, the crystal holder is designed as an annular crystal support. This enables it to support the SiC volume monocrystal, which is essentially cylindrical, in particular in the region of the peripheral edge and the bottom surface, very well. On the other hand, the annular crystal support only contacts a small part of the boundary surfaces of the SiC volume monocrystal, so that a large part of the boundary surfaces is available for heat exchange by means of free heat radiation.

According to a further favorable embodiment, the crystal support has a thickness measured in the axial direction in the range between 1 mm and 5 mm, in particular in the range between 1 mm and 3 mm. The thickness of the crystal support used can also preferably be used to control the heat conduction via the crystal support, which means that the radial thermal gradient in the SiC volume monocrystal to be tempered can also be further adapted and/or adjusted. The thickness of the crystal support is in particular one of the means for adjusting or fine-tuning the ratio between heat conduction and heat radiation, i.e. between the two heat exchange mechanisms with which the SiC volume monocrystal placed on the crystal support exchanges heat with its environment during the thermal post-treatment, in particular with other objects located in its environment or with surrounding free space.

According to another favorable embodiment, a holder material of which the crystal holder consists or which it contains has a lower thermal conductivity than a crucible material of which the post-treatment crucible consists or which it contains. The thermal conductivity of the holder material can also preferably be used to control the heat conduction via the crystal support, which means that the radial thermal gradient in the SiC volume monocrystal to be tempered can be further adapted and/or adjusted. In particular, the thermal conductivity of the holder material is also one of the means for adjusting or fine-tuning the ratio between heat conduction and heat radiation from or to the SiC volume monocrystal to be tempered. The holder material can in particular be graphite. In particular, the crucible material can also be graphite.

According to yet another favorable embodiment, a holder material of which the crystal holder consists or which it contains has a higher porosity than a crucible material of which the post-treatment crucible consists or which it contains. The higher porosity reduces the degree of heat conduction in particular, as there are fewer direct thermal bridges, i.e. fewer direct contact points. The porosity of the holder material can also preferably be used to control the heat conduction via the crystal support, which means that the radial thermal gradient in the SiC volume monocrystal to be tempered can be further adapted and/or adjusted. In particular, the porosity of the holder material is also one of the means for adjusting or fine-tuning the ratio between heat conduction and heat radiation from or to the SiC volume monocrystal to be tempered. The holder material can in particular be a porous graphite. In particular, the crucible material can also be graphite. Graphite is available in various variants. A graphite of the holder material is preferably more porous than a graphite of the crucible material. In particular, the crystal holder can also be implemented as a two-layer or multi-layer structure, which contains, for example, a base body made of a dense first holder material, e.g. made of a dense graphite, and a layer covering the base body made of a second holder material, e.g. made of a porous graphite, which is more porous than the first holder material.

According to a further favorable embodiment, the receiving space is designed to receive the at least one SiC volume monocrystal to be thermally post-treated, wherein the crystal length is at most 50 mm, in particular at most 45 mm. Preferably, the crystal length is between 25 mm and 30 mm. A lower limit value for the crystal length is in particular 15 mm, preferably 25 mm and most preferably 30 mm.

According to another favorable embodiment, the receiving space is designed to receive the at least one SiC volume monocrystal to be thermally post-treated, wherein the crystal diameter is at least 150 mm, in particular at least 200 mm. An upper limit value for the crystal diameter is in particular 450 mm, preferably 300 mm.

According to yet another favorable embodiment, the receiving space is designed to receive the at least one SiC volume monocrystal to be thermally post-treated, wherein an aspect ratio, which is formed by dividing the crystal length by the crystal diameter, is in the range between 0.05 and 0.35, in particular in the range between 0.1 and 0.3.

Other features which are considered as characteristic for the invention are set forth in the appended claims.

Although the invention is illustrated and described herein as being embodied in a method and an apparatus for the thermal post-treatment of at least one silicon carbide (SiC) volume monocrystal, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a first embodiment of an apparatus for the thermal post-treatment of a SiC volume monocrystal with a crystal holder in a post-treatment crucible;

FIG. 2 shows an enlarged portion of the apparatus according to FIG. 1 with the SiC volume monocrystal to be tempered and resting on the crystal holder;

FIGS. 3 to 5 show exemplary embodiments of SiC volume monocrystals to be tempered, each with the same crystal length but different crystal diameters; and

FIGS. 6 to 8 show further exemplary embodiments of apparatuses for thermal post-treatment with other heating devices.

### DETAILED DESCRIPTION OF THE INVENTION

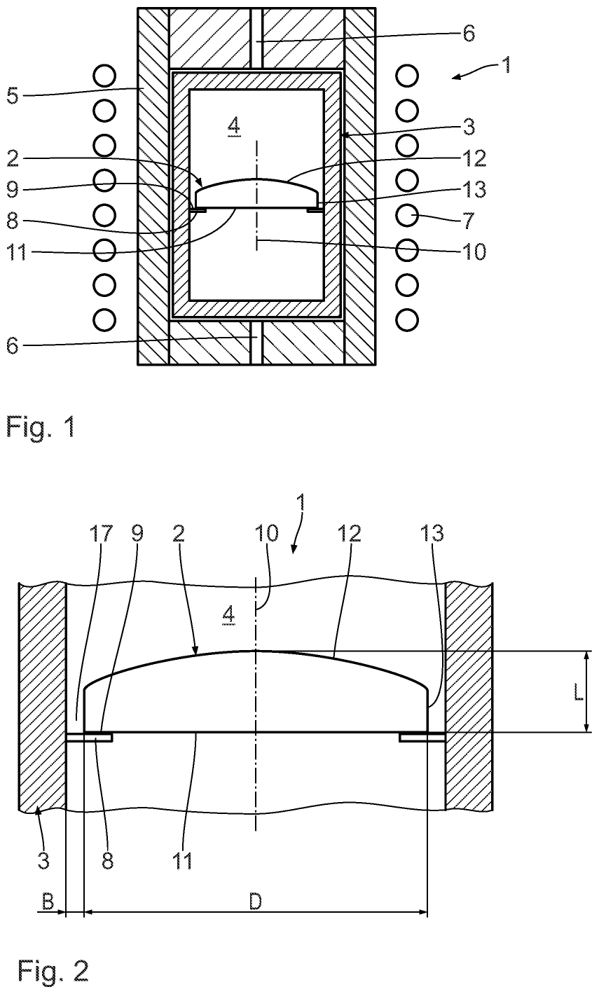

Corresponding parts are labeled with the same reference signs in FIGS. 1 to 8. Details of the exemplary embodiments explained in more detail below may also constitute an invention in themselves or form part of a subject-matter of an invention.

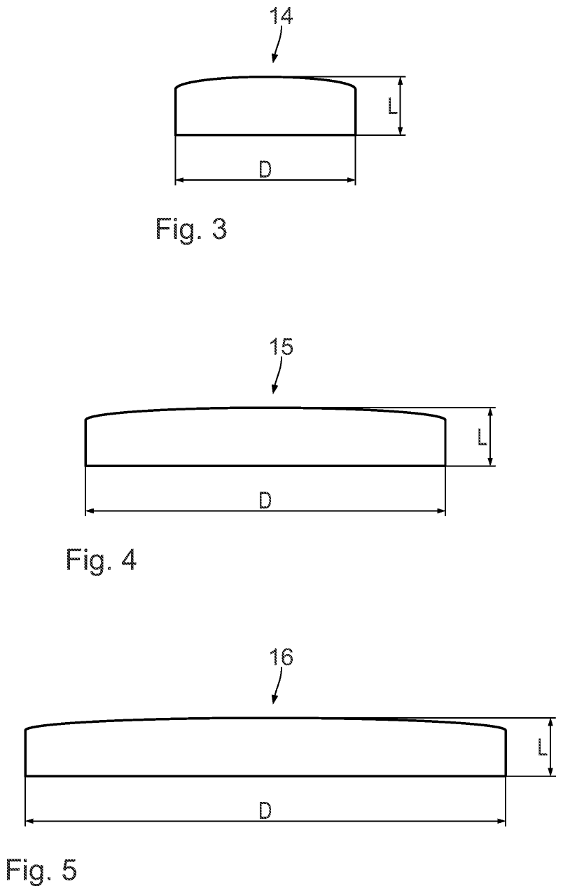

FIGS. 1 and 2 show an exemplary embodiment of an apparatus 1 for the thermal post-treatment of a SiC volume monocrystal 2. The apparatus 1 can also be referred to as a tempering apparatus.

It contains a post-treatment crucible 3, the interior of which forms a receiving space 4 for the SiC volume monocrystal 2 to be thermally post-treated (=tempered). The post-treatment crucible 3 consists of a crucible material, which in the exemplary embodiment is a dense graphite. Alternatively, the crucible material can also be a refractory metal such as tantalum (Ta), tungsten (W) or other refractory metals or carbidized metals, for example tantalum carbide (TaC) or tungsten carbide (WC). The post-treatment crucible 3 is surrounded by thermal insulation 5, which in the exemplary embodiment shown consists of graphite felt. There are two openings in the thermal insulation 5 on the top and bottom, each in the form of a pyrometer channel 6, in order to be able to measure the temperature at the post-treatment crucible 3 using pyrometers not shown. The thermal insulation 5 is surrounded by an inductive heating device in the form of a heating coil 7.

A crystal holder 8 is arranged in the receiving space 4 of the post-treatment crucible 3, which has a holding surface 9 on which the SiC volume monocrystal 2 rests during the thermal post-treatment. The crystal holder 8 is configured as an annular crystal support and, in the exemplary embodiment shown, consists of a holder material that has a higher porosity and lower thermal conductivity compared to the crucible material. In the exemplary embodiment, the holder material is a porous graphite. However, there are also alternative exemplary embodiments in which the holder material has the same or at least similar porosity and thermal conductivity as the crucible material, wherein these two material properties are then not or at most only to a very small extent used as parameters for the (fine) adjustment of the ratio of heat conduction to heat radiation. This adjustment is then carried out almost exclusively via the proportion of the contact-free regions of the total surface area of the SiC volume monocrystal 2 (see below).

The apparatus 1 shown is designed for the thermal post-treatment of only the one SiC volume monocrystal 2. However, this is not a fundamental limitation. There are also other apparatuses in which two or even more SiC volume monocrystals can be tempered together.

According to the enlarged representation of the section of the apparatus 1 shown in FIG. 2, in which the SiC volume monocrystal 2 to be tempered is located during its thermal post-treatment, the SiC volume monocrystal 2 to be tempered has an essentially cylindrical basic shape with a crystal central longitudinal axis 10 and with three boundary surfaces, namely a flat circular bottom surface 11, a cap-shaped top surface 12 and a cylindrical circumferential edge surface 13. The crystal central longitudinal axis 10 runs in the axial direction along which the SiC volume monocrystal 2 has grown during its growth and along which a crystal length L of the SiC volume monocrystal 2 is also measured. In a direction perpendicular thereto, namely in the radial direction, a crystal diameter D of the SiC volume monocrystal 2 is measured.

In the course of growth, mechanical stresses arise in the crystal structure of the growing SiC volume monocrystal 2, which can have an unfavorable effect on the geometry and thus the quality of the SiC substrates later produced from the SiC volume monocrystal 2. For this reason, these stresses should be relieved by a thermal post-treatment of the SiC volume monocrystal 2.

The larger the crystal diameter D of the SiC volume monocrystal 2, the greater the influence of the radial temperature gradient (=thermal gradient) on the properties of the growing SiC volume monocrystal 2 during growth. At the same time, the influence of the axial temperature gradient becomes smaller.

This is also due to the fact that although the physical vapor deposition method used for the crystal growth enables the production of SiC volume monocrystals with increasingly larger crystal diameters D, the achievable crystal length L in the axial direction is limited to a few centimeters. Therefore, the ratio of crystal length L to crystal diameter D, which is referred to here as the aspect ratio, changes with increasing crystal diameter D. It becomes smaller.

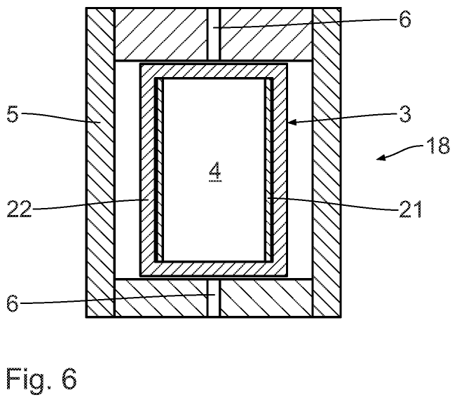

The representations in FIGS. 3 to 5 illustrate this effect. Three SiC volume monocrystals 14, 15 and 16 are shown, each with the same crystal length L of 25 mm, but different crystal diameters D. The SiC volume monocrystal 14 according to FIG. 3 has a crystal diameter D of 76.2 mm and thus an aspect ratio L/D of 0.33. The SiC volume monocrystal 15 according to FIG. 4 has a crystal diameter D of 150 mm and thus an aspect ratio L/D of 0.17. The SiC volume monocrystal 15 according to FIG. 4 has a crystal diameter D of 150 mm and thus an aspect ratio L/D of 0.17. The SiC volume monocrystal 16 according to FIG. 5 has a crystal diameter D of 200 mm and thus an aspect ratio L/D of 0.13.

The increasing influence of the ratios in the radial direction also has an effect on the stresses resulting in the growing SiC volume monocrystal 2, which are increasingly determined by the radial temperature gradient as the crystal diameter D increases.

It has been recognized that this effect must also be considered during thermal post-treatment. In order to achieve the most complete stress relief possible, special temperature conditions are provided in the radial direction in the SiC volume monocrystal 2 during the post-treatment process. Advantageously, an inhomogeneous temperature profile is set with a radial temperature gradient which increases continuously from the crystal central longitudinal axis to the circumferential edge surface.

This special inhomogeneous temperature profile within the SiC volume monocrystal 2 to be tempered is not generated solely by the external heating device of the apparatus 1. The external heating device in the form of the heating coil 7 essentially only directly influences the temperature in the crucible wall of the post-treatment crucible 3. Within the apparatus 1, the post-treatment crucible 3 constitutes a type of heater. It transports the heat fed into it into the receiving chamber 4 in its interior. In order to adjust the temperature profile with an inhomogeneous radial temperature gradient in the SiC volume monocrystal 2, further measures for influencing the temperature are provided in the apparatus 1.

The heat transport mechanism, which transfers the heat from the crucible wall to the inside of the post-treatment crucible 3 to the SiC volume monocrystal 2, also has an influence on the temperature distribution in the SiC volume monocrystal 2.

For instance, it has been found that embedding the SiC volume monocrystal 2 in SiC powder prevents heat transfer by means of heat radiation. Instead, heat conduction is decisive for heat transfer. Furthermore, it has been shown that the SiC powder has a rather insulating and homogenizing influence on the temperature profile within the SiC volume monocrystal 2. An inhomogeneous temperature profile with a radially increasing temperature gradient cannot be set.

A similar effect to complete embedding in SiC powder occurs when the SiC volume monocrystal 2 rests with its entire bottom surface 11 on a support surface, e.g. made of graphite or SiC powder. In the contact region between the bottom surface 11 and the support surface, heat is again transported from and to the SiC volume monocrystal 2 by means of heat conduction.

Another finding is that free heat radiation should be the dominant mechanism for heat transfer from and to the SiC volume monocrystal 2 for setting an inhomogeneous temperature profile with a radially increasing temperature gradient in the SiC volume monocrystal 2. However, there is another mechanism for heat transfer in particular, which is based on heat conduction. The ratio of the proportion of heat conduction in the heat transfer to the proportion of heat radiation in the heat transfer can be used to advantageously set the inhomogeneous temperature profile with the radially increasing temperature gradient from the inside to the outside during the thermal post-treatment. Accordingly, the SiC volume monocrystal 2 is supported or held in the receiving chamber 4 by the crystal holder 8 in such a manner that a significant or predominant proportion of the heat transfer from and to the SiC volume monocrystal 2 takes place by means of free heat radiation. For this purpose, the crystal holder 8 is preferably designed such that the held SiC volume monocrystal 2 has no contact with another object, such as the inner wall of the post-treatment crucible 3 or the holding surface 9 of the crystal holder 8, on the largest part of its total surface area, which is composed of the three boundary surfaces, i.e. the bottom surface 11, the top surface 12 and the circumferential edge surface 13. The heat exchange or heat transfer between the SiC volume monocrystal 2 to be tempered and the free space of the receiving chamber 4 adjacent to it then takes place at these contact-free regions of the total surface area of the SiC volume monocrystal 2 by means of free heat radiation. These contact-free regions form a radiation surface portion which, in relation to the total surface area of the SiC volume monocrystal 2, is in particular in the range between 63% and 83%. At the other regions of the total surface area of the SiC volume monocrystal 2, the proportion of the total surface area of which is accordingly in the range between 17% and 37% in particular, there is contact with other objects or components of the apparatus 1, in particular with the crystal holder 8, so that the heat is transferred there mainly by means of heat conduction.

The heat exchange of the SiC volume monocrystal 2 with the surrounding free space by means of free heat radiation preferably takes place on at least two of the three boundary surfaces, in the exemplary embodiment shown in FIGS. 1 and 2 even on all three boundary surfaces. A central part of the bottom surface 11 is not contacted by the crystal holder 8, which is designed as an annular crystal support. The bottom surface 11 remains contact-free in the region of the annular opening of the crystal holder, so that heat is exchanged there with the adjacent free space by means of free heat radiation. The top surface 12 and the circumferential edge surface 13 are completely contact-free and are thus completely available for heat exchange by means of free heat radiation.

The circumferential edge surface 13 is contact-free, since an inner diameter of the post-treatment crucible 3 is larger than the crystal diameter D of the SiC volume monocrystal 2, so that a tangentially completely circumferential free annular gap 17 is present between the circumferential edge surface 13 of the inserted SiC volume monocrystal 2 and the inner wall of the post-treatment crucible 3. This annular gap 17 has a gap width B of preferably 5 mm to 20 mm (see FIG. 2).

Due to this heat exchange between the SiC volume monocrystal 2 and the surrounding free space by means of free heat radiation, an advantageous inhomogeneous temperature profile with a radially increasing temperature gradient occurs during the thermal post-treatment in the SiC volume monocrystal 2, which leads to the desired reduction of mechanical stresses within the SiC volume monocrystal 2.

As optional additional measures for further adaptation and adjustment of the radial temperature gradient, the thickness of the crystal holder 8, which is designed as an annular crystal support, can be varied and/or a holder material with a correspondingly adapted thermal conductivity or porosity can be used for the crystal holder 8. In particular, a holder material with low thermal conductivity and/or high porosity can be selected.

Apart from the components described above, the apparatus 1 has further constituent parts which, for reasons of clarity, are not shown in FIGS. 1 and 2. There is also at least one evacuation device and a gas device for supplying a controlled gas flow of a process gas and for maintaining the process gas atmosphere during the post-treatment process at an adjustable process gas pressure. The process gas supplied is argon (Ar), helium (He) or nitrogen (N) or a mixture of these gases.

The thermal post-treatment process is described in more detail below.

Before the actual post-treatment process begins, evacuation is carried out to ensure that a controlled atmosphere is achieved and to minimize impurities. Before heating, a process gas pressure in the range from 800 mbar to 1,200 mbar, preferably from 800 mbar to 1,000 mbar, is then set in order to minimize the surface evaporation of SiC material from the SiC volume monocrystal 2 to be tempered.

The post-treatment crucible 3 is then heated to the desired process temperature with the SiC volume monocrystal 2 placed therein, wherein after reaching a temperature range of 900° C. to 1,500° C., preferably 1,000° C. to 1200° C., the further temperature increase up to the actual post-treatment temperature is carried out with a temperature ramp of 1° C./h to 5° C./h in order to avoid the formation of additional stresses. The actual post-treatment temperatures are up to 500° C., preferably up to 200° C., above the growth temperature at which the SiC volume monocrystal 2 was grown. The post-treatment temperature thus ranges from 1,950° C. to 2,450° C.

After the start of the actual thermal post-treatment, the process conditions of pressure, atmospheric composition and temperature are kept as constant as possible for a process period lasting between 5 h and 72 h, preferably between 15 h and 50 h. Minor temperature fluctuations are less than 10° C., preferably less than 2° C. On the one hand, this provides sufficient time for the reduction of mechanical stresses in the crystal structure of the SiC volume monocrystal. On the other hand, stress relief is not hindered by fluctuations in the process parameters.

After the process time has elapsed, the SiC volume monocrystal 2 is cooled slowly with a temperature ramp of 0.5° C./h to 3° C./h, preferably from 0.5° C./h to 2° C./h, to a temperature range of 900° C. to 1,500° C., preferably between 1,000° C. to 1,200° C., in order to avoid the formation of new mechanical stresses due to temperature inhomogeneities that can be caused by heat transport mechanisms. After final cooling of the post-treatment crucible 3 and the tempered SiC volume monocrystal 2 to approximately room temperature, the post-treatment crucible 3 is flooded with ambient atmosphere and the SiC volume monocrystal 2 is removed for further processing.

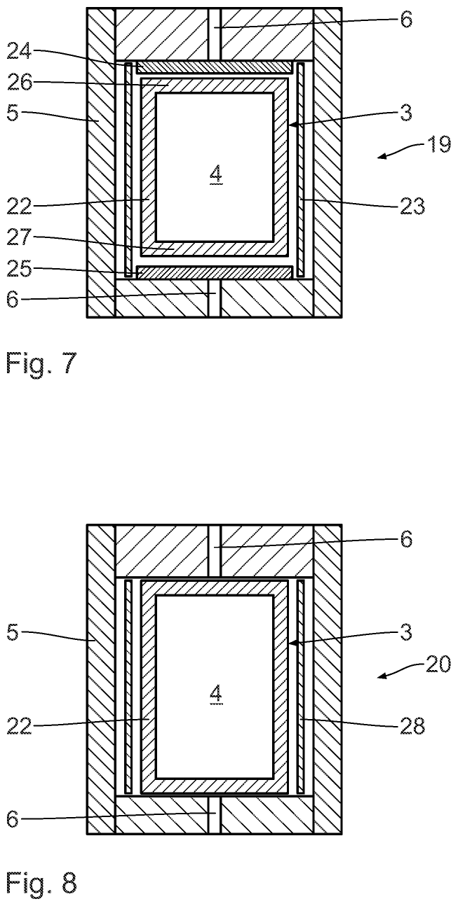

The apparatus 1 according to FIGS. 1 and 2 has an inductive heating device by means of which the global temperature distribution within the post-treatment crucible 3 can be adjusted. However, the heating device does not necessarily have to be designed to be inductive. FIGS. 6 to 8 show alternative tempering apparatuses 18, 19 and 20 for thermal post-treatment of the SiC volume monocrystal 2, which are equipped with resistance heaters instead of the heating coil 7. These resistance heaters can be used to adjust the global temperature distribution within the post-treatment crucible 3 in the same way as the induction heater of the apparatus 1. However, both heating concepts can only ever be used to adjust the temperature of the post-treatment crucible 3 itself. The additional temperature influencing measures described above with reference to the apparatus 1 are advantageously also used with the tempering apparatuses 18, 19, 20, although, like some other components of the tempering apparatuses 18, 19, 20, they are not shown in FIGS. 6 to 8.

In the tempering apparatus 18 according to FIG. 6, a cylindrical resistance heating element 21 is arranged within the post-treatment crucible 3 adjacent to or in contact with the tangentially circumferential cylindrical crucible side wall 22.

In the tempering apparatus 19 shown in FIG. 7, a cylindrical resistance heating element 23 and two circular resistance heating elements 24 and 25 are arranged outside the post-treatment crucible 3, but inside the insulation 5. The resistance heating element 23 surrounds the cylindrical crucible side wall 22. Each of the resistance heating elements 24 and 25 covers the respective axial crucible end wall 26 and 27 on the upper side and underside of the post-treatment crucible 3.

In the tempering apparatus 20 shown in FIG. 8, a cylindrical resistance heating element 28 surrounds the cylindrical crucible side wall 22 outside the post-treatment crucible 3 and inside the insulation 5. The resistance heating element 28 is comparable to the resistance heating element 23 of the tempering apparatus 19. In contrast to the tempering apparatus 19, there are no resistance heating elements on the two axial end faces of the post-treatment crucible 3 in the tempering apparatus 20.

The apparatuses 1, 18, 19 and 20 each have rotationally symmetrical heating devices. These are examples of embodiments. Other, in particular non-rotationally symmetrical structures and alternative arrangements of the heating devices or combinations of different heating devices are also possible.

Overall, all apparatuses 1, 18, 19 and 20 enable a very advantageous thermal post-treatment, in which an inhomogeneous temperature profile with a radially increasing temperature gradient is set within the SiC volume monocrystal 2 to be tempered, corresponding to the stress balance inside the SiC volume monocrystal 2. This leads to a very good reduction of the existing mechanical stresses. High-quality SiC substrates with very low bow and warp can be produced from a SiC volume monocrystal 2 that is thermally post-treated in this manner.

1. A method for the thermal post-treatment of at least one silicon carbide (SiC) volume monocrystal which has a substantially cylindrical basic shape with a crystal length measured in an axial direction, with a crystal diameter measured in a radial direction, with a crystal central longitudinal axis extending in the axial direction, and with three boundary surfaces, namely, a bottom surface, a top surface, and a circumferential edge surface, the method comprising the following steps:
a) bringing the SiC volume monocrystal to a post-treatment temperature to reduce mechanical stresses present in the SiC volume monocrystal after completion of a previous growth, and thereby
b) setting an inhomogeneous temperature profile in the SiC volume monocrystal with a radial thermal gradient, which increases continuously from the crystal central longitudinal axis to the circumferential edge surface; and
c) effecting a heat exchange of the SiC volume monocrystal with a free space surrounding the SiC volume monocrystal by way of free heat radiation on at least two of the three boundary surfaces.

2. The method according to claim 1, which comprises effecting the heat exchange between the SiC volume monocrystal and the surrounding free space by way of free heat radiation at all three boundary surfaces.

3. The method according to claim 1, wherein the heat exchange of the SiC volume monocrystal with the surrounding free space takes place by way of free heat radiation at a radiant surface portion of a total surface area of the SiC volume monocrystal, wherein the total surface area is composed of a sum of the three boundary surfaces and the radiant surface portion lies in a range from 63% to 83% of the total surface area.

4. The method according to claim 1, which comprises setting a radial thermal gradient to take values between 0.1 K/cm and 0.3 K/cm in a central region of the SiC volume monocrystal which extends in the radial direction from the crystal central longitudinal axis to half the crystal diameter.

5. The method according to claim 1, which comprises setting the radial thermal gradient to take values between 0.25 K/cm and 0.8 K/cm in an edge region of the SiC volume monocrystal which extends in the radial direction from half the crystal diameter to the circumferential edge surface.

6. The method according to claim 1, which comprises setting a gas atmosphere around the SiC volume monocrystal by supplying at least one silicon-free process gas.

7. The method according to claim 6, wherein the at least one silicon-free process gas is at least one gas selected from the group consisting of argon, helium, another noble gas, nitrogen, and a gas mixture from the group.

8. The method according to claim 1, wherein the crystal length measured in the axial direction is no more than 50 mm.

9. The method according to claim 1, wherein the crystal diameter measured in the radial direction is at least 150 mm.

10. The method according to claim 1, wherein an aspect ratio, which is formed by dividing the crystal length by the crystal diameter, is in a range between 0.05 and 0.35.

11. An apparatus for the thermal post-treatment of at least one silicon carbide volume monocrystal, which has a substantially cylindrical basic shape with a crystal length measured in an axial direction, with a crystal diameter measured in a radial direction, with a crystal central longitudinal axis extending in the axial direction, and with three boundary surfaces, namely, a bottom surface, a top surface, and a circumferential edge surface, the apparatus comprising:
a) a thermal post-treatment crucible with a receiving space for the at least one SiC volume monocrystal to be thermally post-treated;
b) a heating device (7; 21; 23, 24, 25; 28) for heating the post-treatment crucible and the SiC volume monocrystal to be placed therein to a post-treatment temperature to reduce mechanical stresses present in the SiC volume monocrystal after completion of a previous growth;
c) a crystal holder disposed in said post-treatment crucible with a holding surface for contacting and holding the at least one SiC volume monocrystal to be thermally post-treated;
d) said holding surface being configured to contact the at least one SiC volume monocrystal to be post-treated only in a radial edge region of the SiC volume monocrystal, such that:
d1) in the at least one SiC volume monocrystal to be post-treated, an inhomogeneous temperature profile is established with a radial thermal gradient, which continuously increases from the crystal central longitudinal axis to the circumferential edge surface; and
d2) a heat exchange of the at least one SiC volume monocrystal to be post-treated with a free space surrounding the at least one SiC volume monocrystal takes place by way of free heat radiation on at least two of the three boundary surfaces, wherein the free space is part of said receiving space.

12. The apparatus according to claim 11, wherein an inner diameter of the post-treatment crucible is larger than the crystal diameter and, when the SiC volume monocrystal is inserted in the post-treatment crucible, a tangentially completely circumferential free annular gap is present between the circumferential edge surface of the SiC volume monocrystal and an inner wall of the post-treatment crucible.

13. The apparatus according to claim 11, wherein the crystal holder is an annular crystal support.

14. The apparatus according to claim 13, wherein the crystal support has a thickness, measured in the axial direction, in a range between 1 mm and 5 mm.

15. The apparatus according to claim 11, wherein said crystal holder consists of a holder material and said post-treatment crucible consists of a crucible material, and wherein said holder material has a lower thermal conductivity than said crucible material.

16. The apparatus according to claim 11, wherein said crystal holder contains a holder material and said post-treatment crucible contains a crucible material, and wherein said holder material has a lower thermal conductivity than said crucible material.

17. The apparatus according to claim 11, wherein said crystal holder consists of a holder material and said post-treatment crucible consists of a crucible material, and wherein said holder material of said crystal holder has a higher porosity than said crucible material of said post-treatment crucible.

18. The apparatus according to claim 11, wherein said crystal holder contains a holder material and said post-treatment crucible contains a crucible material, and wherein said holder material of said crystal holder has a higher porosity than said crucible material of said post-treatment crucible.
